(19) United States
(12) Patent Application Publication
(10) Pub. No.: US 2023/0393243 A1
(43) Pub. Date: Dec. 7, 2023

(54) MONOLITHIC INTEGRATION OF FOCAL PLANE SWITCH ARRAY LIDARS WITH CMOS ELECTRONICS

(71) Applicant: nEYE Systems, Inc., Berkeley, CA (US)

(72) Inventors: Ming Chiang A. WU, Piedmont, CA (US); Tae Joon SEOK, El Cerrito, CA (US); Kyungmok KWON, El Cerrito, CA (US); Noriaki KANEDA, Lafayette, CA (US); Xiaosheng ZHANG, Davis, CA (US)

(21) Appl. No.: 18/328,659

(22) Filed: Jun. 2, 2023

Related U.S. Application Data
(60) Provisional application No. 63/348,367, filed on Jun. 2, 2022.

(51) Int. Cl. G01S 7/481; B81B 3/00

(52) U.S. Cl. CPC G01S 7/4811; B81B 2201/045; B81B 3/0083; G01S 7/4817

(57) ABSTRACT

The present disclosure is directed to imaging LiDARs monolithic integration of focal plane switch array LiDARS with CMOS electronics. The CMOS wafer contains electronic circuits needed to control the focal plane array, e.g., digital addressing circuits and MEMS drivers, as well as circuits to amplify and process the detected signals, e.g., trans-impedance amplifiers (TIA), multi-stage amplifiers, analog-to-digital converters (ADC), digital signal processing (DSP), and circuits to communicate with external systems. Methods of use are also provided.

### PRIORITY CLAIM

This patent application claims priority to U.S. provisional patent application No. 63/348,367, titled “MONOLITHIC INTEGRATION OF FOCAL PLANE SWITCH ARRAY LIDARS WITH CMOS ELECTRONICS” and filed on Jun. 2, 2022, which is herein incorporated by reference in its entirety.

### FIELD

The present disclosure details novel LiDAR systems and methods. More specifically, this disclosure is directed to imaging LiDARs with features to increase the performance and reliability of silicon photonic LiDARs.

### BACKGROUND

Light detection and ranging (LiDAR) is widely used in autonomous vehicles and portable devices such as smartphones and tablets. Solid state LiDARs are particularly attractive because they are conducive to miniaturization and mass production. US Patent Pub. No. 2021/0116778 teaches a beamsteering system consisting of a programmable array of vertical couplers (also called optical antennas) located at the focal plane of an imaging lens. Optical signal can be delivered to any selected optical antenna through a programmable optical network consisting of MEMS (micro-electro-mechanical system)-actuated waveguide switches. Compared with conventional thermo-optic or electro-optic switches, MEMS switches offer lower insertion loss, lower crosstalk, broadband operation, and digital actuation. High density arrays of programmable optical antennas can be integrated on single chips for high resolution imaging LiDARs, thanks to their small footprint.

Solid state LiDARs with focal plane switch arrays are usually fabricated on silicon-on-insulator or bulk silicon wafers. In previous implementations, external photodetectors and electronic controllers were used. It is desirable to integrate complementary metal-oxide semiconductor (CMOS) electronics to control the switch array as well as to detect, amplify, and process the reflected optical signals. Some foundries offer limited capabilities to integrate silicon photonics with CMOS electronics or germanium detectors on bulk CMOS. However, integration of photonic integrated circuits, MEMS actuators and CMOS electronics monolithically has not been previously disclosed.

### SUMMARY

An electronic system is provided, comprising: a complementary metal-oxide semiconductor (CMOS) wafer; a photonic integrated circuit (PIC) disposed on the CMOS wafer, the PIC including: an array of light emitters disposed on the CMOS wafer; an optical switch disposed on the CMOS wafer and coupled to the array of light emitters; an optical array disposed on the CMOS wafer and including a plurality of optical antennas having transmit and receive functions; a programmable optical network disposed on the CMOS wafer and configured to provide a light path from the optical switch to a selected optical antenna; first CMOS electronic circuits disposed on the CMOS wafer and configured to control the programmable optical network; and second CMOS electronic circuits disposed on the CMOS wafer and configured to amplify and process signals detected by the optical array.

In some aspects, the first CMOS electronic circuits are selected from the group consisting of digital addressing circuits, and micro-electro-mechanical system (MEMS) drivers.

In one aspect, the second CMOS electronic circuits are selected from the group consisting of trans-impedance amplifiers (TIA), multi-stage amplifiers, analog-to-digital converters (ADC), digital signal processing (DSP), and circuits to communicate with external systems.

In another aspect, a passivation layer inserted between the PIC and the CMOS.

In one aspect, the passivation layer comprises silicon dioxide.

In some aspects, the optical switch comprises a micro-electro-mechanical system (MEMS) switch.

In another aspect, the passivation layer is configured to protect the first and second CMOS electronic circuits from a release etch performed during manufacturing to free up the MEMS switch.

In some aspects, the passivation layer is configured to provide a lower cladding layer for the PIC to reduce optical loss.

In another aspect, a semiconductor optical amplifier (SOA) is integrated on the PIC.

In some aspects, the PIC is fabricated on a handle wafer and attached to the CMOS wafer.

In other aspects, the PIC is directly fabricated on the CMOS wafer.

In some aspects, one or more photodetectors are disposed on the CMOS wafer.

In some aspects, the one or more photodetectors comprise germanium photodetectors.

In some aspects, a semiconductor optical amplifier (SOA) is integrated on the PIC.

In one aspect, an integrated laser is formed on the PIC with the SOA and an optical cavity.

A fast programmable photonic integrated circuit (FP-PIC) is provided, comprising: a focal plane switch array (FPSA); a complementary metal-oxide semiconductor (CMOS) electrically coupled to the FPSA, the CMOS comprising: a signal detection block configured to receive and process optical signals from the FPSA; a FPSA control block configured to control the FPSA; and a central control and timing block configured to control and synchronize the FPSA with the signal detection block.

In one aspect, the signal detection block further comprises one or more photodetectors.

In another aspect, the signal detection block further comprises one or more amplifiers.

In some aspects, the signal detection block further comprises an analog-to-digital converter (ADC).

In another aspect, the signal detection block further comprises a digital signal processing unit (DSP).

In one aspect, the FPSA control block further comprises micro-electro-mechanical system (MEMS) drivers.

In another aspect, the FPSA control block further comprises a row and column selection controller.

In some aspects, the FPSA control block further comprises a digital interface.

In one aspect, a digital I/O is configured to communicate 3D data to external systems.

In another aspect, an optical phase locked loop (OPLL) is integrated on the CMOS to linearize an optical frequency sweep from a laser or modulator.

In one aspect, a laser source is integrated on the CMOS.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIG. 1 shows one example of monolithic integration of focal plane switch array (FPSA) with CMOS electronics.

FIG. 2 shows a cross-sectional view of one embodiment of a focal plane switch array LiDAR on CMOS after release etch.

FIG. 3 shows a cross-sectional view of an embodiment with semiconductor lasers and optical amplifiers integrated with the PIC and CMOS.

FIG. 4 shows a schematic illustration of the operation of a focal plane switch array LiDAR on CMOS.

FIG. 5 is a schematic illustration of the operation of a focal plane switch array LiDAR on CMOS with CMOS performing optical phased locked loops (OPLL) or linearization of laser frequency sweep.

FIG. 6 is a schematic illustrating the operation of focal plane switch array LiDAR with integrated lasers and semiconductor optical amplifiers (SOAs) on CMOS.

### DETAILED DESCRIPTION

Our previous patent application (U.S. Ser. No. 17/687,372, incorporated herein in its entirety) describes a solid-state light detection and ranging (LiDAR) with focal-plane switch array (FPSA). Each pixel in the array is mapped to a distinctive direction within the field of view of the imaging lens. The laser power is delivered to a given pixel through an integrated optical switch network. The reflected light from a target is either collected by the same optical antenna (monostatic architecture) or a separate optical antenna (pseudo-monostatic architecture) and sent to receivers to analyze the time of flight. In this architecture, each laser powers a selected row of pixels at a time. Multiple lasers can be used to operate multiple rows at the same time to speed up the operation. However, these lasers need to be individually controlled to provide optimum modulation. For example, in continuous-wave frequency-modulated (FMCW) LiDAR, linear frequency modulation is required for each laser.

This disclosure is related to monolithic integration of FPSAs with complementary metal-oxide semiconductor (CMOS) electronics, including a FPSA LiDAR. The focal plane array photonic integrated circuits (PICS) and micro-electromechanical systems (MEMS) switches are fabricated with low temperature processes compatible with post-processing of CMOS wafers. Sufficiently low processing temperatures may be utilized to better ensure CMOS circuits will not be disturbed. CMOS provides electronic circuits to detect, amplify, and process optical signals as well as the control circuits of the switches in the focal plane array.

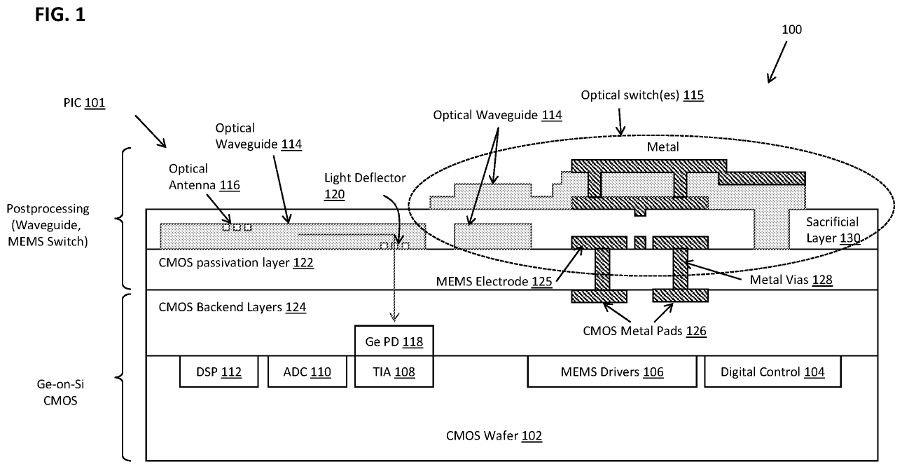

A schematic cross-section of an embodiment of fast programmable photonic integrated circuit (FP-PIC) 100 that includes a FPSA PIC 101 with CMOS electronics is shown in FIG. 1. The CMOS wafer 102 contains electronic circuits configured to control the focal plane array, including but not limited to digital addressing circuits 104 and MEMS drivers 106, as well as circuits configured to amplify and process the detected signals, including but not limited to, trans-impedance amplifiers (TIA) 108, multi-stage amplifiers (not shown), analog-to-digital converters (ADC) 110, digital signal processing (DSP) 112, and circuits configured to communicate with external systems (e.g., Bluetooth, wifi, radio, IR, or other wireless communication protocols). One embodiment of the PIC comprises one or more optical input waveguides 114, a programmable optical network (not shown) to deliver the optical signals to a selected set of pixels comprising optical switches 115 and optical antennas 116, and a matched programmable optical network (not shown) to connect the selected receive optical antennas to one or more photodetectors 118 (e.g., a germanium photodiode or photodetector). In the illustrated example, one or more light deflectors 120 such as gratings or mirrors can be configured to couple the receive optical antennas to the one or more photodetectors. In one embodiment, the optical switches in the programmable optical network are made of MEMS optical switches.

The PIC 101 can be fabricated on a separate wafer and attached to the CMOS wafer 102, e.g., by flip-chip bonding, or directly fabricated on the CMOS wafers as shown in FIG. 1. In the case of direct fabrication on the CMOS wafer, a CMOS passivation layer 122 such as silicon dioxide can be inserted between the PIC 101 and the CMOS wafer 102. This passivation layer can serve several purposes: 1) to protect the CMOS circuits from the release etch process that will be performed later during manufacturing to free up the MEMS structures; and 2) to provide a lower cladding layer for the PIC to reduce optical loss. One or more CMOS backend layers 124 can provide metal interconnect or inter-metallic dielectric between the PIC and the CMOS electronics.

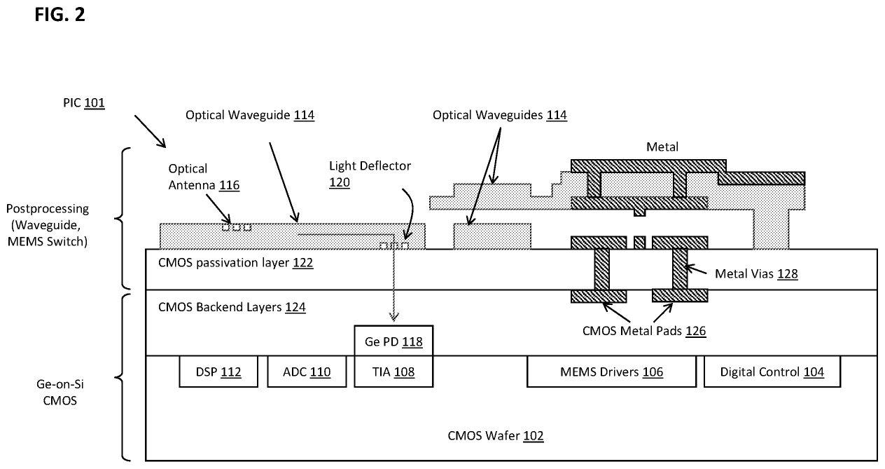

The optical waveguides 114 in the PIC can be realized using dielectric materials such as silicon, silicon nitride, or aluminum oxide deposited at a sufficiently low temperature (<˜450° C.) to avoid damaging the CMOS circuits, though higher temperatures may also be employed. MEMS electrode(s) 125 (e.g., aluminum structures) can be connected to CMOS metal pads 126 through metal vias 128. The PIC 101 may also include coupler waveguides, MEMS actuators, and a sacrificial layer 130 that can be selectively removed, e.g., amorphous silicon can be selectively etched by XeF2 gas or other known etching process. A schematic cross-section of the released structure is shown in FIG. 2.

While the embodiment in FIGS. 1-2 uses electrostatic actuators, other actuators such as piezoelectric, thermal, magnetic, electromagnetic, or others can be used.

The embodiment in FIGS. 1-2 also includes germanium photodetectors. The Ge-on-Si CMOS process is available in commercial foundries. For LiDARs operating at 1310 nm or 1550 nm range, InGaAs, InGaAsP, SiGeSn, or other photodiodes can be used. Polysilicon photodiodes with sub-bandgap absorption are used sometime because they are easy to integrate, though the efficiency is lower. For LiDARs operating at shorter wavelengths, silicon photodiode can be used.

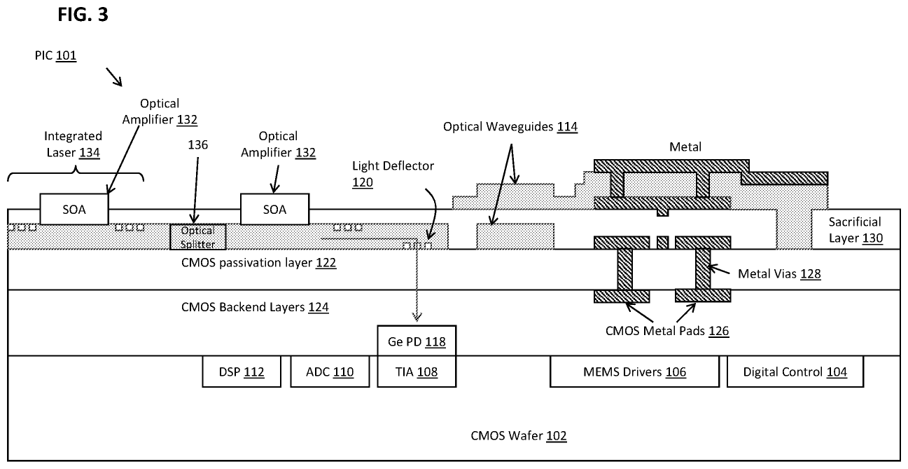

In another embodiment, a semiconductor gain element, called a semiconductor optical amplifier (SOA) 132, can also be integrated on the PIC 101, as illustrated in FIG. 3. On-chip integrated lasers 134 can be constructed by combining the SOA with an optical cavity. The optical cavity can be formed on the waveguide using, for example, reflectors, distributed Bragg reflectors, or mirroring resonators. The on-chip laser can power multiple optical antennas through an optical splitter 136. Additional SOAs can be integrated to compensate for the optical splitting loss and further boost up the optical power at each of the optical antennas. The SOA can be integrated with the PIC by wafer-bonding, including molecular bonding and adhesive bonding, or by epitaxial growth.

This embodiment in FIG. 3 uses dielectric waveguides, metal electrodes, and sacrificial amorphous silicon 130. Other combination of waveguide, electrode, and sacrificial materials are possible. For example, silicon or amorphous silicon can be used as waveguide materials, tungsten or doped polysilicon as the metal electrodes, silicon dioxide as a sacrificial material, and silicon nitride as a passivation layer.

In addition to direct deposition and patterning of thin film materials on CMOS wafers, other embodiments herein integrate the PIC with CMOS using wafer bonding technology. In this embodiment, the PIC can be fabricated on a handle wafer before bonding face-to-face to the CMOS wafers. Any known bonding methods can be used, e.g., metal-to-metal bonding, dielectric-to-dielectric bonding, adhesive bonding, anodic bonding, etc. The substrate of the PIC is removed after wafer bonding, and the bonded wafer is ready for release etch.

The disclosed PIC on CMOS can be used in applications other than LiDAR. For example, it can be used for large scale optical switches, such as those described in U.S. application Ser. No. 15/109,761.

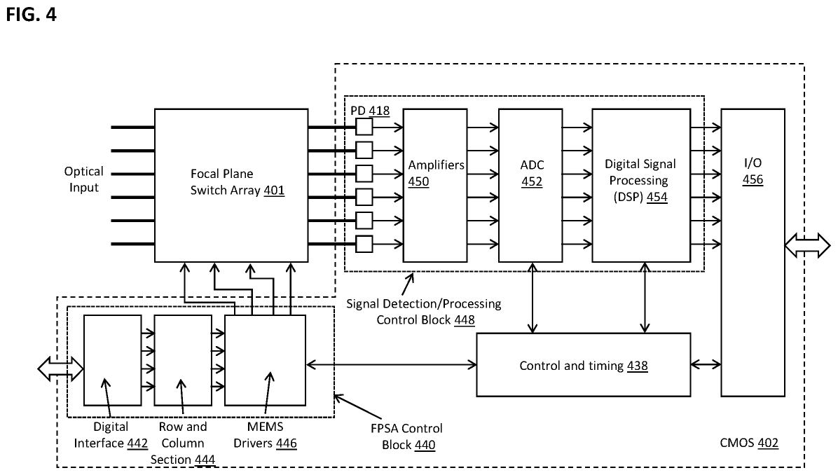

FIG. 4 illustrates the functions and the operation of some embodiments of a fast programmable photonic integrated circuit of this disclosure that includes a FPSA 401 and a CMOS 402. The function of the FPSA has been described in U.S. application Ser. No. 17/252,671, which is incorporated herein by reference in its entirety. The CMOS functions include three parts: (1) a central control and timing block 438; (2) a FPSA control block 440 with a digital interface 442, row and column selection 444, and MEMS drivers 446; and (3) a signal detection/processing block 448. The central control and timing block 438 provides a centralized control and synchronizes the FPSA 401 with the signal detection/processing block 448. The MEMS drivers provide high voltage control signals for electrostatic actuators (or control signals customized to other types of actuators). The signal detection/processing block 448 includes photodetectors 418, trans-impedance amplifiers (TIA) 450 and potentially additional amplifiers, analog-to-digital converters (ADC) 452, and digital signal processing (DSP) unit 454 to perform fast Fourier transform (FFT) and other functions. For coherent LiDAR such as frequency-modulation continuous-wave (FMCW) LiDAR, the reflected signals are mixed with local oscillators before detected by the PDs. Finally, the 3D data (angular coordinates, position, velocity, intensity) is sent to external systems through the digital I/O 456. Some of the CMOS functions can be implemented on external chips, e.g., the DSP functions or accelerators can be on a separate integrated circuit chip or system-on-chip (SOC).

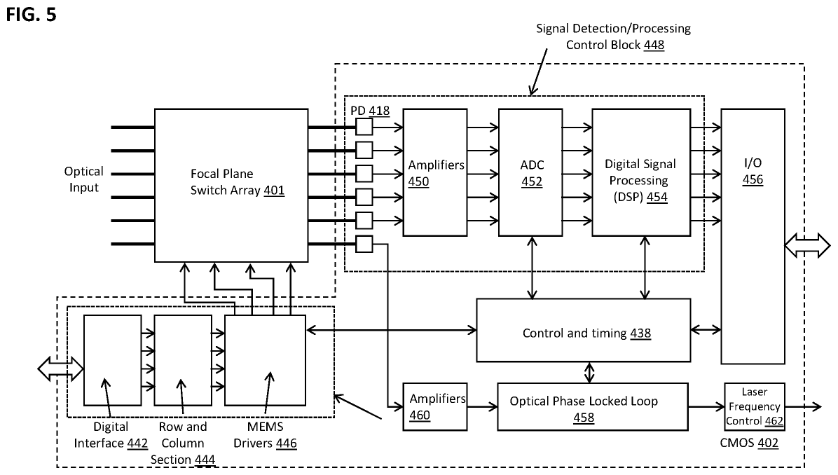

In another embodiment, optical phase locked loop (OPLL) 458 can be integrated on CMOS along with one or more amplifiers 460 and a laser frequency control 462 to linearize the optical frequency sweep from the laser or modulator, as illustrated in FIG. 5.

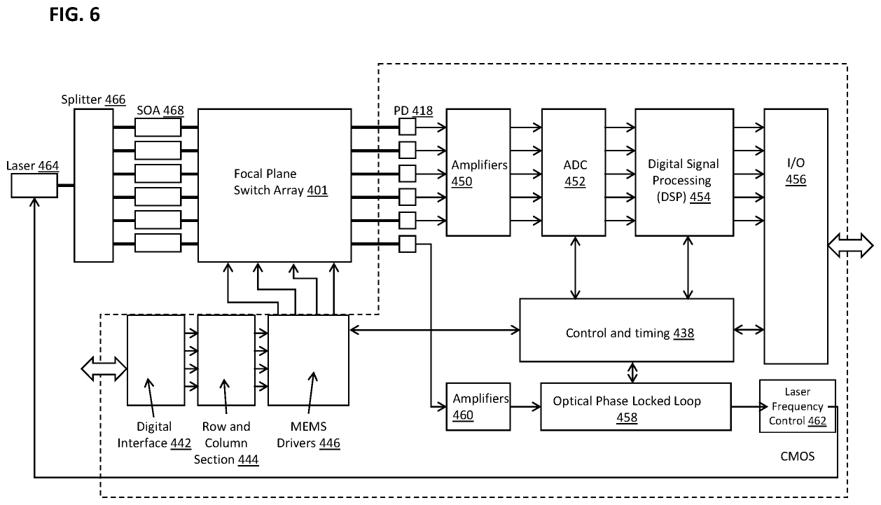

In another embodiment, semiconductor laser sources 464, splitter(s) 466, and semiconductor optical amplifiers (SOAs) 468 can be integrated with the PIC on CMOS, as illustrated in FIG. 6. The laser gain elements and SOAs can be integrated by wafer bonding or epitaxial growth.

The integrated single-chip PIC on CMOS offers many advantages over prior existing technologies, including the integration greatly reduces the number of I/O pads of the PIC. Previously, each row and each column have a separate I/O pad. For example, the 128×128 array has 256 I/O pads for the MEMS switches. With integrated CMOS, only a small digital bus is needed to input all the switch configurations and scanning patterns. The scanning pattern can even be stored on the memory on chip. The integrated system is much more compact and much easier to package, which enables a standard core that is customizable to address specific application requirements.

The integrated photodetectors and amplifiers offer higher sensitivity and lower noise. The integrated system also has much lower parasitic capacitance, which affords the ability to greatly reduce power consumption. The integrated ADC enables a smaller footprint than a stand-alone ADC. Additionally, the integrated FPSA on CMOS enables greatly reduced I/O bandwidth. Instead of outputting the entire detected waveform, the integrated system will output only the range, velocity, and intensity for each pixel. The FPSA PIC of the present invention addresses legacy limitations of cost, reliability, size and weight and thereby expand the potential LiDAR applications in automotive, drone, robotic and consumer markets.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

What is claimed is:

1. An electronic system comprising:
a complementary metal-oxide semiconductor (CMOS) wafer;
a photonic integrated circuit (PIC) disposed on the CMOS wafer, the PIC including:
an array of light emitters disposed on the CMOS wafer;
an optical switch disposed on the CMOS wafer and coupled to the array of light emitters;
an optical array disposed on the CMOS wafer and including a plurality of optical antennas having transmit and receive functions;
a programmable optical network disposed on the CMOS wafer and configured to provide a light path from the optical switch to a selected optical antenna;
first CMOS electronic circuits disposed on the CMOS wafer and configured to control the programmable optical network; and
second CMOS electronic circuits disposed on the CMOS wafer and configured to amplify and process signals detected by the optical array.

2. The system of claim 1, wherein the first CMOS electronic circuits are selected from the group consisting of digital addressing circuits, and micro-electro-mechanical system (MEMS) drivers.

3. The system of claim 1, wherein the second CMOS electronic circuits are selected from the group consisting of trans-impedance amplifiers (TIA), multi-stage amplifiers, analog-to-digital converters (ADC), digital signal processing (DSP), and circuits to communicate with external systems.

4. The system of claim 1, further comprising a passivation layer inserted between the PIC and the CMOS.

5. The system of claim 4, wherein the passivation layer comprises silicon dioxide.

6. The system of claim 4, wherein the optical switch comprises a micro-electro-mechanical system (MEMS) switch.

7. The system of claim 6, wherein the passivation layer is configured to protect the first and second CMOS electronic circuits from a release etch performed during manufacturing to free up the MEMS switch.

8. The system of claim 4, wherein the passivation layer is configured to provide a lower cladding layer for the PIC to reduce optical loss.

9. The system of claim 1, further comprising a semiconductor optical amplifier (SOA) integrated on the PIC.

10. The system of claim 1, wherein the PIC is fabricated on a handle wafer and attached to the CMOS wafer.

11. The system of claim 1, wherein the PIC is directly fabricated on the CMOS wafer.

12. The system of claim 1, further comprising one or more photodetectors disposed on the CMOS wafer.

13. The system of claim 1, wherein the one or more photodetectors comprise germanium photodetectors.

14. The system of claim 1, further comprising a semiconductor optical amplifier (SOA) integrated on the PIC.

15. The system of claim 14, further comprising an integrated laser formed on the PIC with the SOA and an optical cavity.

16. A fast programmable photonic integrated circuit (FP-PIC), comprising:
a focal plane switch array (FPSA);
a complementary metal-oxide semiconductor (CMOS) electrically coupled to the FPSA, the CMOS comprising:
a signal detection block configured to receive and process optical signals from the FPSA;
a FPSA control block configured to control the FPSA; and
a central control and timing block configured to control and synchronize the FPSA with the signal detection block.

17. The FP-PIC of claim 16, wherein the signal detection block further comprises one or more photodetectors.

18. The FP-PIC of claim 16, wherein the signal detection block further comprises one or more amplifiers.

19. The FP-PIC of claim 16, wherein the signal detection block further comprises an analog-to-digital converter (ADC).

20. The FP-PIC of claim 16, wherein the signal detection block further comprises a digital signal processing unit (DSP).
